(19) United States
(12) Patent Application Publication
(10) Pub. No.: US 2023/0378383 A1
(43) Pub. Date: Nov. 23, 2023

(54) DETECTION DEVICE AND METHOD FOR MANUFACTURING THE SAME

(71) Applicant: Japan Display Inc., Tokyo (JP)

(72) Inventors: Kazuki MATSUNAGA, Tokyo (JP); Shigesumi ARAKI, Tokyo (JP)

(21) Appl. No.: 18/227,785

(22) Filed: Jul. 28, 2023

Related U.S. Application Data
(63) Continuation of application No. PCT/JP2022/000245, filed on Jan. 6, 2022.

(30) Foreign Application Priority Data
Feb. 2, 2021 (JP) 2021-014986

(51) Int. Cl. H01L 31/0232; H01L 31/10

(52) U.S. Cl. CPC H01L 31/0232; H01L 31/10

(57) ABSTRACT

According to an aspect, a detection device includes: a first substrate; a plurality of photodiodes provided on the first substrate; and an optical filter layer including a plurality of light-transmitting regions provided so as to overlap the respective photodiodes, a light-blocking region provided between the light-transmitting regions, and a projection projecting from a surface of the light-blocking region facing the first substrate.

### CROSS-REFERENCE TO RELATED APPLICATION

This application claims the benefit of priority from Japanese Patent Application No. 2021-014986 filed on Feb. 2, 2021 and International Patent Application No. PCT/JP2022/000245 filed on Jan. 6, 2022, the entire contents of which are incorporated herein by reference.

### BACKGROUND

### 1. Technical Field

What is disclosed herein relates to a detection device and a method for manufacturing the same.

### 2. Description of the Related Art

Japanese Patent Application Laid-open Publication No. 2020-067834 describes a detection device that includes a plurality of positive-intrinsic-negative (PIN) photodiodes. Japanese Patent Application Laid-open Publication No. 2009-110452 (JP-A-2009-110452) describes an imaging device that includes photodetection elements that detect light, a display layer, and a lens array in which a plurality of lenses are arranged (described as light-condensing means for refracting light in JP-A-2009-110452). The imaging device of JP-A-2009-110452 is also provided with an optical filter layer (collimator in JP-A-2009-110452) that removes oblique light components incident on the photodetection elements.

A positional misalignment generated between the optical filter layer and the photodetection elements causes variations in amount of light incident on the photodetection elements, which may reduce the detection accuracy.

### SUMMARY

According to an aspect, a detection device includes: a first substrate; a plurality of photodiodes provided on the first substrate; and an optical filter layer including a plurality of light-transmitting regions provided so as to overlap the respective photodiodes, a light-blocking region provided between the light-transmitting regions, and a projection projecting from a surface of the light-blocking region facing the first substrate.

According to an aspect, a method for manufacturing a detection device includes: forming a plurality of photodiodes on a first substrate; forming an optical filter layer comprising a plurality of light-transmitting regions, a light-blocking region provided between the light- transmitting regions, and a projection projecting from an upper side of the light-blocking region; and bonding the first substrate to the second substrate such that the projection is located between the adjacent photodiodes in plan view in a direction orthogonal to the first substrate.

### BRIEF DESCRIPTION OF THE DRAWINGS

FIG. 1A is a sectional view illustrating a schematic sectional configuration of a detection apparatus having an illumination device, the detection apparatus including a detection device according to an embodiment;

FIG. 1B is a sectional view illustrating a schematic sectional configuration of the detection apparatus having an illumination device, the detection apparatus including the detection device according to a first modification of the embodiment;

FIG. 1C is a sectional view illustrating a schematic sectional configuration of the detection apparatus having an illumination device, the detection apparatus including the detection device according to a second modification of the embodiment;

FIG. 1D is a sectional view illustrating a schematic sectional configuration of the detection apparatus having an illumination device, the detection apparatus including the detection device according to a third modification of the embodiment;

FIG. 2 is a plan view illustrating the detection device according to the embodiment;

FIG. 3 is a block diagram illustrating a configuration example of the detection device according to the embodiment;

FIG. 4 is a circuit diagram illustrating a detection element;

FIG. 5 is a sectional view along V-V′ of FIG. 2;

FIG. 6 is sectional view schematically illustrating a photodiode;

FIG. 7 is a plan view illustrating an optical filter layer;

FIG. 8 is an explanatory diagram for schematically explaining an arrangement relation of projections of the optical filter layer with photodiodes and a sensor insulating film of an array substrate;

FIG. 9 is a sectional view along IX-IX' of FIG. 7;

FIG. 10 is an explanatory diagram illustrating a use example of the detection device, which is disposed so as to face a finger;

FIG. 11 is an explanatory diagram for explaining an exemplary method for manufacturing the detection device;

FIG. 12 is a sectional view schematically illustrating a detection device according to a second embodiment;

FIG. 13 is a sectional view schematically illustrating a detection device according to a third embodiment;

FIG. 14 is an explanatory diagram for schematically explaining an arrangement relation of the projections of the optical filter layer with the photodiodes and the sensor insulating film of the array substrate of a detection device according to a fourth embodiment; and

FIG. 15 is a sectional view schematically illustrating the detection device according to the fourth embodiment.

### DETAILED DESCRIPTION

The following describes modes (embodiments) for carrying out the present disclosure in detail with reference to the drawings. The present disclosure is not limited to the description of the embodiments given below. Components described below include those easily conceivable by those skilled in the art or those substantially identical thereto. In addition, the components described below can be combined as appropriate. What is disclosed herein is merely an example, and the present disclosure naturally encompasses appropriate modifications easily conceivable by those skilled in the art while maintaining the gist of the present disclosure. To further clarify the description, the drawings may schematically illustrate, for example, widths, thicknesses, and shapes of various parts as compared with actual aspects thereof. However, they are merely examples, and interpretation of the present disclosure is not limited thereto. The same component as that described with reference to an already mentioned drawing is denoted by the same reference numeral through the present disclosure and the drawings, and detailed description thereof may not be repeated where appropriate.

In the present specification and claims, in expressing an aspect of disposing another structure on or above a certain structure, a case of simply expressing “on” includes both a case of disposing the other structure immediately on the certain structure so as to contact the certain structure and a case of disposing the other structure above the certain structure with still another structure interposed therebetween, unless otherwise specified.

### First Embodiment

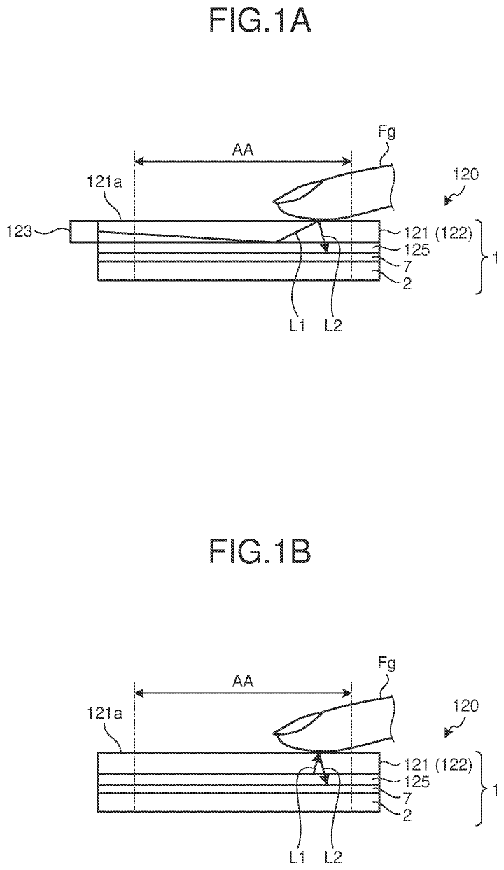

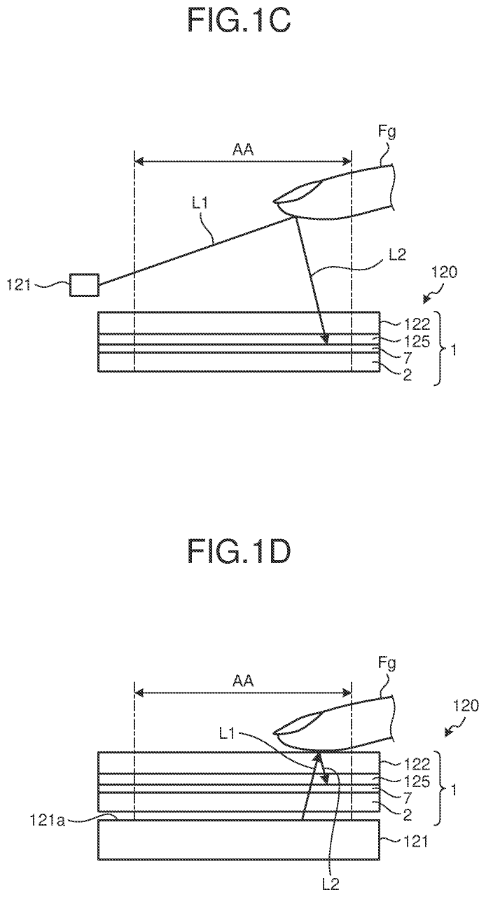

FIG. 1A is a sectional view illustrating a schematic sectional configuration of a detection apparatus having an illumination device, the detection apparatus including a detection device according to an embodiment. FIG. 1B is a sectional view illustrating a schematic sectional configuration of the detection apparatus having an illumination device, the detection apparatus including the detection device according to a first modification of the embodiment. FIG. 1C is a sectional view illustrating a schematic sectional configuration of the detection apparatus having an illumination device, the detection apparatus including the detection device according to a second modification of the embodiment. FIG. 1D is a sectional view illustrating a schematic sectional configuration of the detection apparatus having an illumination device, the detection apparatus including the detection device according to a third modification of the embodiment.

As illustrated in FIG. 1A, a detection apparatus 120 having an illumination device includes a detection device 1 and an illumination device 121. The detection device 1 includes an array substrate 2, an optical filter 7, an adhesive layer 125, and a cover member 122. That is, the array substrate 2, the optical filter 7, the adhesive layer 125, and the cover member 122 are stacked in this order in a direction orthogonal to a surface of the array substrate 2. As will be describe later, the cover member 122 of the detection device 1 can be replaced with the illumination device 121. The adhesive layer 125 only needs to bond the optical filter 7 to the cover member 122. Hence, the detection device 1 may have a structure without the adhesive layer 125 in a region corresponding to a detection region AA. When the adhesive layer 125 is not provided in the detection region AA, the detection device 1 has a structure in which the adhesive layer 125 bonds the cover member 122 to the optical filter 7 in a region corresponding to a peripheral region GA outside the detection region AA. The adhesive layer 125 provided in the detection region AA may be simply paraphrased as a “protective layer” for the optical filter 7.

As illustrated in FIG. 1A, the illumination device 121 may be, for example, what is called a side light-type front light that uses the cover member 122 as a light guide plate provided in a position corresponding to the detection region AA of the detection device 1 and that includes a plurality of light sources 123 arranged at one end or both ends of the cover member 122. That is, the cover member 122 has a light-emitting surface 121a for emitting light and serves as one component of the illumination device 121. The illumination device 121 emits light L1 from the light-emitting surface 121a of the cover member 122 toward a finger Fg that serves as a detection target. For example, a light-emitting diode (LED) that emits light in a predetermined color is used as a light source.

As illustrated in FIG. 1B, the illumination device 121 may include a light source (such as an LED) provided immediately below the detection region AA of the detection device 1. The illumination device 121 including the light source doubles as the cover member 122.

The illumination device 121 is not limited to the example of FIG. 1B. As illustrated in FIG. 1C, the illumination device 121 may be provided on a lateral side or an upper side of the cover member 122 and may emit the light L1 to the finger Fg from the lateral side or the upper side of the finger Fg.

Furthermore, as illustrated in FIG. 1D, the illumination device 121 may be what is called a direct-type backlight that includes a light source (such as an LED) provided in the detection region of the detection device 1.

The light L1 emitted from the illumination device 121 is reflected as light L2 by the finger Fg serving as the detection target. The detection device 1 detects the light L2 reflected by the finger Fg to detect asperities (such as a fingerprint) on a surface of the finger Fg. The detection device 1 may further detect information on a living body by detecting the light L2 reflected in the finger Fg, in addition to detecting the fingerprint. Examples of the information on the living body include a vascular image of veins or the like, pulsation, and pulse waves. The color of the light L1 from the illumination device 121 may be varied depending on the detection target.

The cover member 122 is a member for protecting the array substrate 2 and the optical filter 7, and covers the array substrate 2 and the optical filter 7. The illumination device 121 may have a structure to double as the cover member 122, as described above. In the structures illustrated in FIGS. 1C and 1D in which the cover member 122 is separate from the illumination device 121, the cover member 122 is a glass substrate, for example. The cover member 122 is not limited to the glass substrate and may be a resin substrate, for example. The cover member 122 may be omitted. In that case, a surface of the array substrate 2 and the optical filter 7 is provided with a protective layer of an insulating film or the like, and the finger Fg contacts the protective layer of the detection device 1.

The detection apparatus 120 having an illumination device may be provided with a display panel instead of the illumination device 121, as illustrated in FIG. 1B. The display panel may be, for example, an organic electroluminescent (EL) (organic light-emitting diode (OLED)) display panel or an inorganic EL (micro-LED or mini-LED) display. Alternatively, the display panel may be a liquid crystal display (LCD) panel using liquid crystal elements as display elements or an electrophoretic display (EPD) panel using electrophoretic elements as the display elements. Even in those cases, the fingerprint of the finger Fg and the information on the living body can be detected based on the light L2 obtained by reflecting, by the finger Fg, display light (light L1) emitted from the display panel.

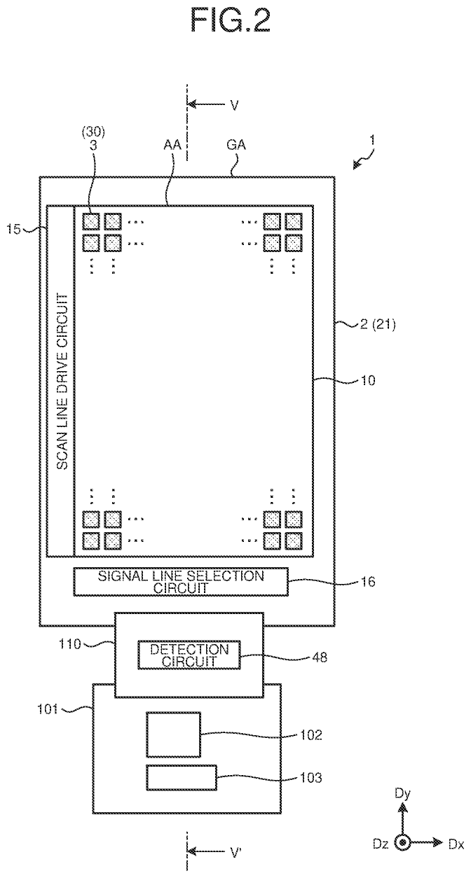

FIG. 2 is a plan view illustrating the detection device according to the embodiment. A first direction Dx illustrated in FIG. 2 and the subsequent drawings is one direction in a plane parallel to a first substrate 21. A second direction Dy is one direction in the plane parallel to the first substrate 21 and is a direction orthogonal to the first direction Dx. The second direction Dy may non-orthogonally intersect the first direction Dx. A third direction Dz is a direction orthogonal to the first direction Dx and the second direction Dy, and is a direction normal to the first substrate 21. The term “plan view” refers to a positional relation when viewed in the third direction Dz.

As illustrated in FIG. 2, the detection device 1 includes the array substrate 2 (first substrate 21), a sensor 10, a scan line drive circuit 15, a signal line selection circuit 16, a detection circuit 48, a control circuit 102, and a power supply circuit 103.

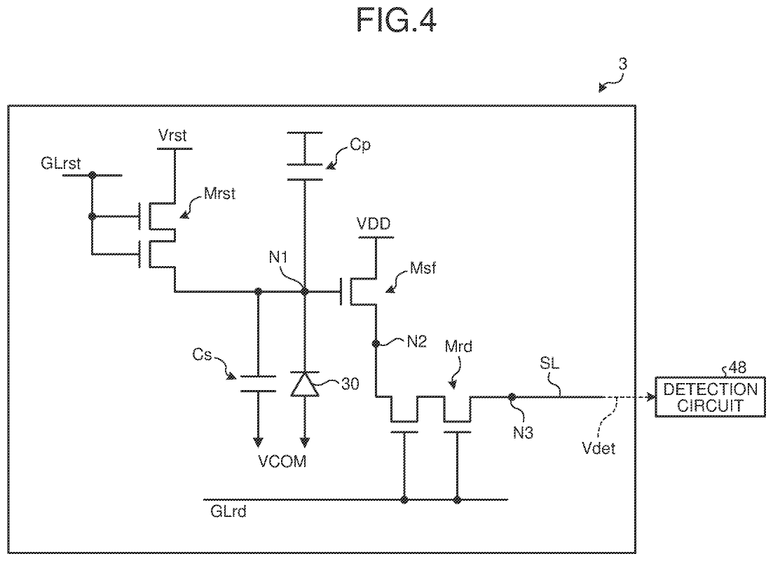

The first substrate 21 is electrically coupled to a control substrate 101 through a wiring substrate 110. The wiring substrate 110 is, for example, a flexible printed circuit board or a rigid circuit board. The wiring substrate 110 is provided with the detection circuit 48. The control substrate 101 is provided with the control circuit 102 and the power supply circuit 103. The control circuit 102 is, for example, a field-programmable gate array (FPGA). The control circuit 102 supplies control signals to the sensor 10, the scan line drive circuit 15, and the signal line selection circuit 16 to control an operation of the sensor 10. The power supply circuit 103 supplies voltage signals including, for example, a power supply potential VDD and a reference potential VCOM (refer to FIG. 4) to the sensor 10, the scan line drive circuit 15, and the signal line selection circuit 16. In the present embodiment, the case is exemplified where the detection circuit 48 is disposed on the wiring substrate 110, but the present disclosure is not limited to this case. The detection circuit 48 may be disposed on the first substrate 21.

The first substrate 21 has the detection region AA and the peripheral region GA. The detection region AA and the peripheral region GA extend in planar directions parallel to the first substrate 21. Each element (detection element 3) of the sensor 10 is provided in the detection region AA. The peripheral region GA is a region outside the detection region AA and is a region not provided with each element (detection element 3). That is, the peripheral region GA is a region between the outer periphery of the detection region AA and the ends of the first substrate 21. The scan line drive circuit 15 and the signal line selection circuit 16 are provided in the peripheral region GA. The scan line drive circuit 15 is provided in a region extending along the second direction Dy in the peripheral region GA. The signal line selection circuit 16 is provided in a region extending along the first direction Dx in the peripheral region GA and is provided between the sensor 10 and the detection circuit 48.

Each of the detection elements 3 of the sensor 10 is an optical sensor including a photodiode 30 as a sensor element. The photodiode 30 is a photoelectric conversion element and outputs an electrical signal corresponding to light irradiating each of the photodiodes 30. More specifically, the photodiode 30 is an organic photodiode (OPD). Alternatively, the photodiode 30 may be a positive-intrinsic-negative (PIN) photodiode. The detection elements 3 are arranged in a matrix having a row-column configuration in the detection region AA. The photodiode 30 included in each of the detection elements 3 performs the detection in accordance with gate drive signals (for example, a reset control signal RST and a read control signal RD) supplied from the scan line drive circuit 15. Each of the photodiodes 30 outputs the electrical signal corresponding to the light irradiating the photodiode 30 as a detection signal Vdet to the signal line selection circuit 16. The detection device 1 detects the information on the living body based on the detection signals Vdet received from the photodiodes 30.

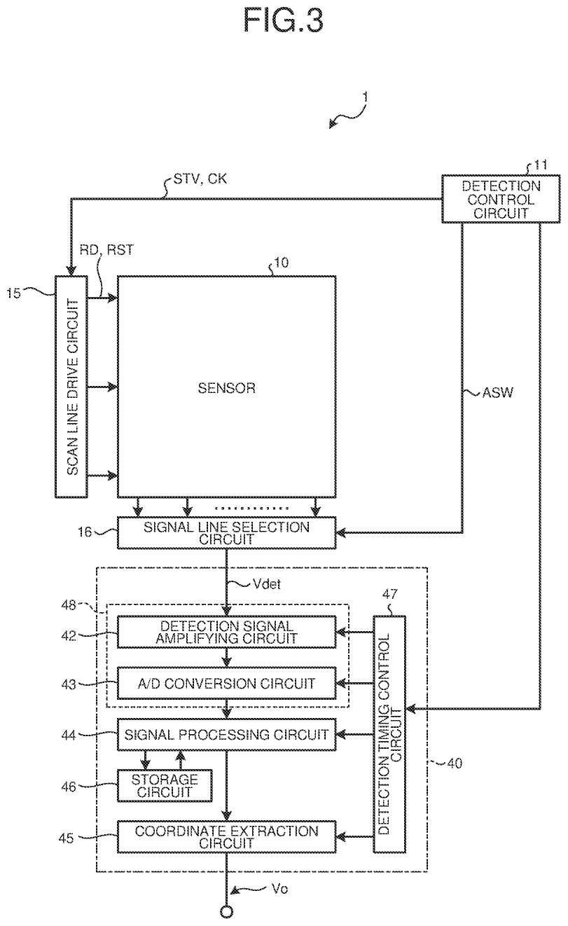

FIG. 3 is a block diagram illustrating a configuration example of the detection device according to the embodiment. As illustrated in FIG. 3, the detection device 1 further includes a detection control circuit 11 and a detector 40. The control circuit 102 includes one, some, or all functions of the detection control circuit 11. The control circuit 102 also includes one, some, or all functions of the detector 40 other than those of the detection circuit 48.

The detection control circuit 11 is a circuit that supplies respective control signals to the scan line drive circuit 15, the signal line selection circuit 16, and the detector 40 to control operations of these components. The detection control circuit 11 supplies various control signals including, for example, a start signal STV and a clock signal CK to the scan line drive circuit 15. The detection control circuit 11 also supplies various control signals including, for example, a selection signal ASW to the signal line selection circuit 16.

The scan line drive circuit 15 is a circuit that drives a plurality of scan lines (read control scan line GLrd and reset control scan line GLrst (refer to FIG. 4)) based on the various control signals. The scan line drive circuit 15 sequentially or simultaneously selects the scan lines, and supplies the gate drive signals (for example, the reset control signals RST and the read control signals RD) to the selected scan lines. Through this operation, the scan line drive circuit 15 selects the photodiodes 30 coupled to the scan lines.

The signal line selection circuit 16 is a switch circuit that sequentially or simultaneously selects a plurality of output signal lines SL (refer to FIG. 4). The signal line selection circuit 16 is, for example, a multiplexer. The signal line selection circuit 16 couples the selected output signal lines SL to the detection circuit 48 based on the selection signal ASW supplied from the detection control circuit 11. Through this operation, the signal line selection circuit 16 outputs the detection signals Vdet of the photodiodes 30 to the detector 40.

The detector 40 includes the detection circuit 48, a signal processing circuit 44, a coordinate extraction circuit 45, a storage circuit 46, and a detection timing control circuit 47. The detection timing control circuit 47 performs control to cause the detection circuit 48, the signal processing circuit 44, and the coordinate extraction circuit 45 to operate in synchronization with one another based on a control signal supplied from the detection control circuit 11.

The detection circuit 48 is, for example, an analog front-end (AFE) circuit. The detection circuit 48 is a signal processing circuit having functions of at least a detection signal amplifying circuit 42 and an analog-to-digital (A/D) conversion circuit 43. The detection signal amplifying circuit 42 amplifies the detection signal Vdet, and is an integration circuit, for example. The A/D conversion circuit 43 converts an analog signal output from the detection signal amplifying circuit 42 into a digital signal.

The signal processing circuit 44 is a logic circuit that detects a predetermined physical quantity received by the sensor 10 based on output signals of the detection circuit 48. The signal processing circuit 44 can detect asperities on the surface of the finger Fg or a palm based on the signals from the detection circuit 48 when the finger Fg is in contact with or in proximity to a detection surface. The signal processing circuit 44 may detect the information on the living body based on the signals from the detection circuit 48. Examples of the information on the living body include the vascular image, the pulse waves, the pulsation, and a blood oxygen saturation level of the finger Fg or the palm.

The storage circuit 46 temporarily stores therein signals calculated by the signal processing circuit 44. The storage circuit 46 may be, for example, a random-access memory (RAM) or a register circuit.

The coordinate extraction circuit 45 is a logic circuit that obtains detected coordinates of the asperities on the surface of the finger Fg or the like when the contact or proximity of the finger Fg is detected by the signal processing circuit 44. The coordinate extraction circuit 45 is the logic circuit that also obtains detected coordinates of blood vessels of the finger Fg or the palm. The coordinate extraction circuit 45 combines the detection signals Vdet output from the respective detection elements 3 of the sensor 10 to generate two-dimensional information representing a shape of the asperities on the surface of the finger Fg or the like. The coordinate extraction circuit 45 may output the detection signals Vdet as sensor outputs Vo instead of calculating the detected coordinates.

The following describes a circuit configuration example of the detection device 1. FIG. 4 is a circuit diagram illustrating the detection element. As illustrated in FIG. 4, the detection element 3 includes the photodiode 30, a reset transistor Mrst, a read transistor Mrd, and a source follower transistor Msf. The reset transistor Mrst, the read transistor Mrd, and the source follower transistor Msf are provided correspondingly to each of the photodiodes 30. The reset transistor Mrst, the read transistor Mrd, and the source follower transistor Msf are each formed of an n-type thin-film transistor (TFT). However, each of the transistors is not limited thereto, and may be formed of a p-type TFT.

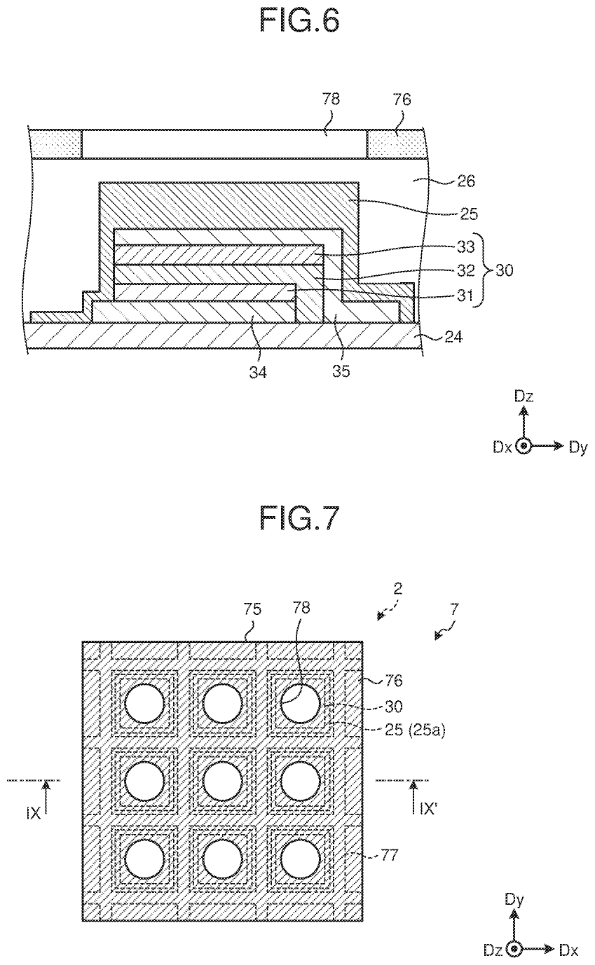

The reference potential VCOM is applied to the anode of the photodiode 30. The cathode of the photodiode 30 is coupled to a node N1. The node N1 is coupled to a capacitive element Cs, one of the source and the drain of the reset transistor Mrst, and the gate of the source follower transistor Msf. The node N1 further has parasitic capacitance Cp. When light is incident on the photodiode 30, a signal (electric charge) output from the photodiode 30 is stored in the capacitive element Cs. The capacitive element Cs is, for example, capacitance generated between an upper conductive layer 35 and a lower conductive layer 34 that are coupled to the photodiode 30 (refer to FIG. 6). The parasitic capacitance Cp is capacitance added to the capacitive element Cs, and is capacitance generated between various types of wiring and electrodes provided on the array substrate 2.

The gate of the reset transistor Mrst is coupled to the reset control scan line GLrst. The other of the source and the drain of the reset transistor Mrst is supplied with a reset potential Vrst. After the reset transistor Mrst is turned on (into a conduction state) in response to the reset control signal RST, the potential of the node N1 is reset to the reset potential Vrst. The reference potential VCOM is lower than the reset potential Vrst, and thus, the photodiode 30 is driven in a reverse bias state.

The source follower transistor Msf is coupled between a terminal supplied with the power supply potential VDD and the read transistor Mrd (node N2). The gate of the source follower transistor Msf is coupled to the node N1. The gate of the source follower transistor Msf is supplied with a signal (electric charge) generated by the photodiode 30. This operation causes the source follower transistor Msf to output a voltage signal corresponding to the signal (electric charge) generated by the photodiode 30 to the read transistor Mrd.

The read transistor Mrd is coupled between the source of the source follower transistor Msf (node N2) and a corresponding one of the output signal lines SL (node N3). The gates of the read transistor Mrd are coupled to the read control scan line GLrd. After the read transistor Mrd is turned on in response to the read control signal RD, the signal output from the source follower transistor Msf, that is, the voltage signal corresponding to the signal (electric charge) generated by the photodiode 30 is output as the detection signal Vdet to the output signal line SL.

In the example illustrated in FIG. 4, the reset transistor Mrst and the read transistor Mrd each have what is called a double-gate structure configured by coupling two transistors in series. However, the structures of those transistors are not limited thereto, and the reset transistor Mrst and the read transistor Mrd may have a single-gate structure, or a multi-gate structure including three or more transistors coupled in series. The circuit of each of the detection elements 3 is not limited to the configuration including the three transistors of the reset transistor Mrst, the source follower transistor Msf, and the read transistor Mrd. The detection element 3 may include two transistors, or four or more transistors.

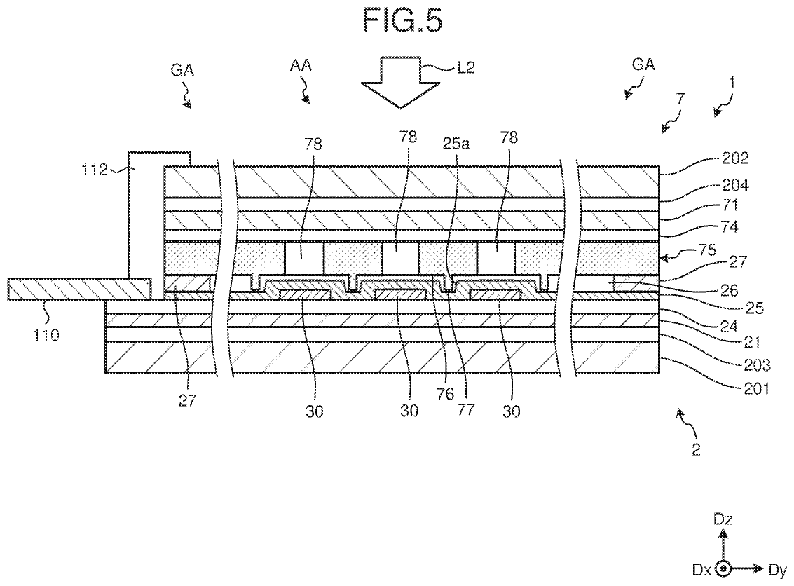

The following describes a detailed configuration of the detection elements 3 and the optical filter 7. FIG. 5 is a sectional view along V-V′ of FIG. 2. FIG. 5 schematically illustrates the multilayered configuration of the array substrate 2, the photodiodes 30, and the optical filter 7.

As illustrated in FIG. 5, the array substrate 2 includes a protective film 201, an adhesive layer 203, the first substrate 21, a TFT layer 24, the photodiodes 30, and a sensor insulating film 25. The first substrate 21 is bonded on the protective film 201 with the adhesive layer 203 interposed therebetween. The first substrate 21 is a resin substrate of, for example, polyimide. The adhesive layer 203 is, for example, a film of optically clear adhesive (OCA).

In the present specification, a direction from the first substrate 21 toward a second substrate 71 in a direction orthogonal to the first substrate 21 is referred to as “upper side” or simply “above”. A direction from the second substrate 71 toward the first substrate 21 is referred to as “lower side” or simply “below”. The term “plan view” refers to a positional relation as viewed in the direction orthogonal to the first substrate 21.

The TFT layer 24 is provided on the first substrate 21. The TFT layer 24 is a layer in which various transistors such as the reset transistor Mrst, the read transistor Mrd, and the source follower transistor Msf (refer to FIG. 4) and wiring coupled to them are formed.

The photodiodes 30 are arranged on the TFT layer 24 of the array substrate 2. The sensor insulating film 25 is provided on the TFT layer 24 so as to cover the photodiodes 30. The sensor insulating film 25 is, for example, an inorganic insulating film, and is provided as a sealing film that reduces penetration of water from the outside into the photodiodes 30. The sensor insulating film 25 is not limited to a single layer and may be configured by stacking a plurality of insulating films.

FIG. 6 is sectional view schematically illustrating the photodiode. As illustrated in FIG. 6, the photodiode 30 includes a hole transport layer 31, an active layer 32, and an electron transport layer 33. The photodiode 30 is an organic photodiode (OPD) in which the active layer 32 is formed of an organic semiconductor.

More specifically, the lower conductive layer 34, the hole transport layer 31, the active layer 32, the electron transport layer 33, and the upper conductive layer 35 are stacked on the TFT layer 24 in the order as listed. The lower conductive layer 34 is formed of a metal material such as aluminum (Al). The upper conductive layer 35 is formed of, for example, a light-transmitting conductive material such as indium tin oxide (ITO). The sensor insulating film 25 is provided so as to cover the upper conductive layer 35.

FIG. 6 illustrates the example in which the photodiode 30 is an OPD formed of an organic semiconductor, but the photodiode 30 is not limited to this example. The photodiode 30 may be, for example, a PIN photodiode formed of an inorganic semiconductor.

Referring back to FIG. 5, the optical filter 7 is provided above the photodiodes 30. The optical filter 7 is an optical element that transmits and blocks components of the light L2 reflected by an object to be detected, such as the finger Fg. Of the light L2 reflected by an object to be detected, components that travel in the third direction Dz toward the photodiodes 30 are transmitted by the optical filter 7, and components that travel in oblique directions are blocked by the optical filter 7. The optical filter 7 is also called collimating apertures or a collimator.

The optical filter 7 includes a protective film 202, an adhesive layer 204, the second substrate 71, a barrier film 74, an optical filter layer 75, and a sealing member 27. The optical filter 7 is bonded to the array substrate 2 with an adhesive layer 26 and the sealing member 27 interposed therebetween. The optical filter layer 75 of the optical filter 7 is provided above the photodiodes 30 and the sensor insulating film 25 with the adhesive layer 26 interposed therebetween. The adhesive layer 26 is formed of, for example, an optical clear resin (OCR) that is a liquid ultraviolet (UV) curable resin.

The sealing member 27 is provided at the periphery of the peripheral region GA and seals between the optical filter 7 (optical filter layer 75) and the array substrate 2 (sensor insulating film 25). In addition, a terminal protective film 112 is provided so as to cover a region between the periphery of the optical filter 7 and the wiring substrate 110.

The optical filter layer 75 includes a plurality of light-transmitting regions 78, a light-blocking region 76, and a plurality of projections 77. Each of the light-transmitting regions 78 is provided so as to overlap a corresponding one of the photodiodes 30. The light-transmitting region 78 is formed of, for example, a light-transmitting resin material and has a column shape continuous from the upper surface to the lower surface of the optical filter layer 75. In more detail, the light-transmitting region 78 has a circular cylindrical shape formed in a circular shape in plan view. The light-blocking region 76 is provided between the adjacent light-transmitting regions 78 and provided so as to overlap a region between the photodiodes 30. The light-blocking region 76 is formed of, for example, a resin material colored in black. The projections 77 are provided so as to project from a surface of the light-blocking region 76 facing the first substrate 21.

The second substrate 71 is disposed so as to face the first substrate 21. The optical filter layer 75 and the photodiodes 30 are provided between the first substrate 21 and the second substrate 71 in the third direction Dz. More specifically, the second substrate 71 is bonded to the lower surface of the protective film 202, that is, a surface thereof facing the first substrate 21, with the adhesive layer 204 interposed therebetween. A resin substrate such as polyimide is used as the second substrate 71. The adhesive layer 204 is, for example, a film of optically clear adhesive (OCA).

The optical filter layer 75 is provided to a surface of the second substrate 71 facing the first substrate 21 with the barrier film 74 interposed therebetween. The barrier film 74 is an inorganic insulating film, for example.

With the configuration described above, the light L2 reflected by the object to be detected, such as the finger Fg, passes through the light-blocking region 76 and is incident on the photodiodes 30. The light traveling in the oblique directions is blocked by the light-blocking region 76 and the projections 77. As a result, the detection device 1 can reduce occurrences of what is called crosstalk between the adjacent photodiodes 30.

The first substrate 21 and the second substrate 71 are formed of a resin material such as polyimide, and thus, the detection device 1 can be configured as a flexible sensor deformable along the shape of the object to be detected, such as the finger Fg. However, the first substrate 21 and the second substrate 71 are not limited thereto and may be glass substrates of, for example, quartz or alkali-free glass. In that case, the protective films 201 and 202 and the adhesive layers 203 and 204 can be omitted.

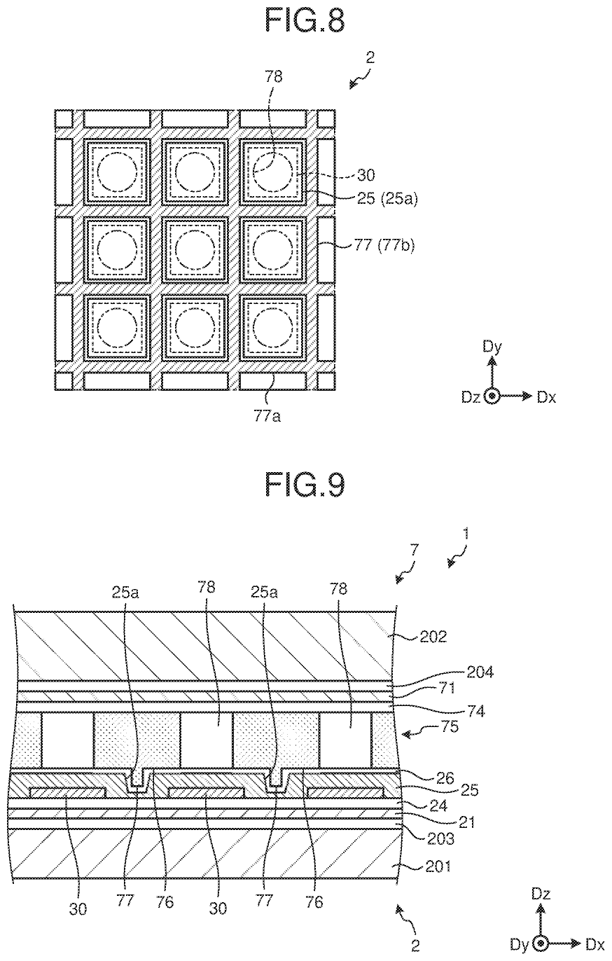

The following describes a detailed configuration of the projections 77 of the optical filter layer 75 with reference to FIGS. 7 to 9. FIG. 7 is a plan view illustrating the optical filter layer. FIG. 8 is an explanatory diagram for schematically explaining an arrangement relation of the projections of the optical filter layer with the photodiodes and the sensor insulating film of the array substrate. FIG. 9 is a sectional view along IX-IX′ of FIG. 7. FIG. 7 illustrates the light-blocking region 76 of the optical filter layer 75 with oblique lines. FIG. 8 illustrates portions (projections 77) of the optical filter layer 75, with the projections 77 being shaded with oblique lines.

As illustrated in FIGS. 7 and 8, the photodiodes 30 are arranged in the first direction Dx and the second direction Dy. The light-transmitting regions 78 of the optical filter layer 75 are arranged in a matrix having a row-column configuration in the first direction Dx and the second direction Dy and are each provided so as to overlap a corresponding one of the photodiodes 30. The light-transmitting region 78 is circular in plan view. However, the light-transmitting region 78 may have other shapes, such as a quadrilateral shape and a polygonal shape.

The projections 77 are formed in a grid pattern and are provided between the adjacent photodiodes 30. In other words, the projections 77 are provided in a frame shape surrounding each of the photodiodes 30.

More specifically, as illustrated in FIG. 8, the projections 77 include a plurality of first portions 77a and a plurality of second portions 77b that intersect the first portions 77a. In plan view, each of the first portions 77a is provided between the photodiodes 30 adjacent in the second direction Dy, and extends in the first direction Dx. In addition, the first portions 77a are arranged in the second direction Dy. In plan view, each of the second portions 77b is provided between the photodiodes 30 adjacent in the first direction Dx, and extends in the second direction Dy. In addition, the second portions 77b are arranged in the first direction Dx.

As illustrated in FIG. 9, the sensor insulating film 25 is provided with a groove 25a between the adjacent photodiodes 30. Each of the projections 77 is provided in a position overlapping the groove 25a. In other words, at least a portion of the projection 77 is located between side surfaces of the groove 25a in the first direction Dx. FIG. 9 illustrates the sectional view along the first direction Dx. Similarly, in a sectional view along the second direction Dy, at least a portion of the projection 77 is located between side surfaces of the groove 25a in the second direction Dy.

This configuration allows the detection device 1 to reduce the planar positional misalignment between the optical filter layer 75 and the photodiodes 30. That is, since the optical filter layer 75 and the array substrate 2 are accurately arranged such that the light-transmitting regions 78 overlap the respective photodiodes 30, the detection device 1 can reduce variations in amount of light incident on the photodiodes 30 and occurrences of moiré caused by the positional misalignment of the light-transmitting regions 78.

The projection 77 projects from the lower surface of the light-blocking region 76 toward the first substrate 21. An end of the projection 77 is provided so as to extend to the vicinity of the bottom of the groove 25a between the adjacent photodiodes 30. The projection 77 is formed of a resin material colored in the same manner as the light-blocking region 76. This configuration allows the projections 77 to effectively block the light traveling in the oblique directions through the adjacent light-transmitting regions 78 between the adjacent photodiodes 30, and thus can reduce the occurrences of what is called crosstalk. As described above, the projections 77 are provided in a frame shape surrounding each of the photodiodes 30. Therefore, the light can be blocked more effectively than, for example, a case where the projections 77 are formed in a pin shape.

The adhesive layer 26 is provided between the end of the projection 77 and the bottom of the groove 25a. The end of the projection 77 is away from the bottom of the groove 25a. The end of the projection 77 is not limited to this configuration and may be in contact with the bottom or a portion of a sidewall of the groove 25a. The projections 77 are not limited to being continuously formed in the first direction Dx and the second direction Dy and may be formed so as to be divided into a plurality of portions with slits or the like provided therebetween.

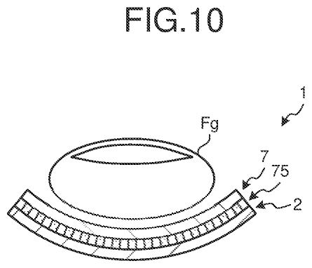

FIG. 10 is an explanatory diagram illustrating a use example of the detection device, which is disposed so as to face the finger. In the example illustrated in FIG. 10, a flexible resin substrate is used for the first substrate 21 of the array substrate 2 and the second substrate 71 of the optical filter 7, and the detection device 1 is configured as a deformable (bendable) flexible sensor.

As illustrated in FIG. 10, the optical filter 7 (optical filter layer 75) of the detection device 1 is disposed so as to face the surface of the finger Fg and is curved in a concave shape along the shape of the surface of the finger Fg. In this case, compressive stress is generated in the optical filter 7 (optical filter layer 75).

Since the detection device 1 is provided with the projections 77, the detection device 1 can reduce the positional misalignment between the array substrate 2 and the optical filter 7 even when the device is deformed to be bent. A resin material having lower elasticity than that of the light-transmitting resin material constituting the light-transmitting regions 78 can be used as the projections 77. This reduces failure and peeling of the optical filter layer 75 even when the optical filter layer 75 is deformed to be bent.

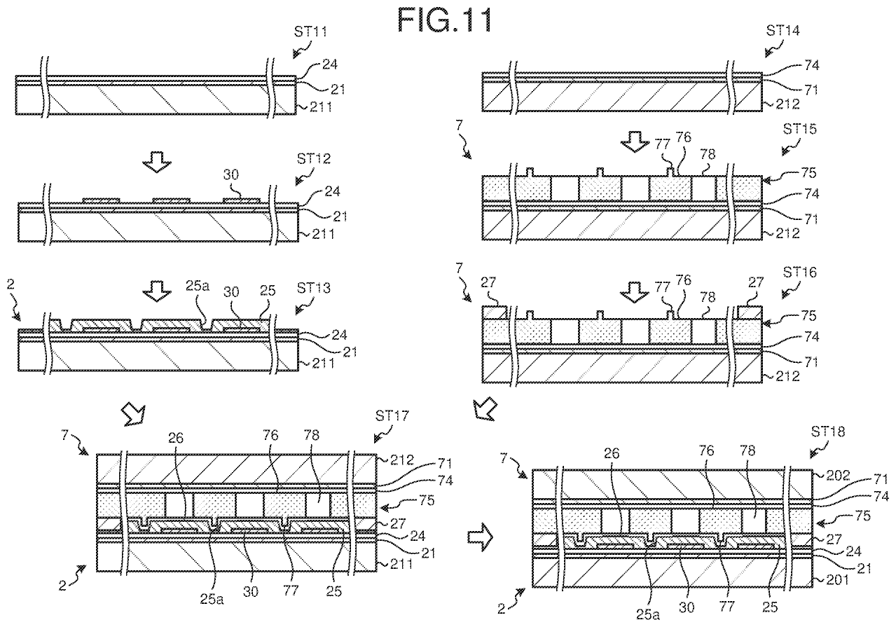

The following describes a manufacturing process of the detection device 1. FIG. 11 is an explanatory diagram for explaining an exemplary method for manufacturing the detection device. The method for manufacturing the detection device 1 illustrated in FIG. 11 includes a process of forming the array substrate 2 (Steps ST11, ST12, and ST13), a process of forming the optical filter 7 (Steps ST14, ST15, and ST16), and a process of assembling the detection device 1 by bonding together the array substrate 2 and the optical filter 7 (Steps ST17 and ST18).

The process of forming the array substrate 2 will first be described. As illustrated in FIG. 11, the first substrate 21 and the TFT layer 24 are formed on one surface of a support substrate 211 (Step ST11). The first substrate 21 is formed by applying a material of the first substrate 21 on the support substrate 211 and curing the applied material. The support substrate 211 is a glass substrate, for example, and has higher stiffness than that of the first substrate 21. The various transistors and the various types of wiring that constitute the TFT layer 24 are formed above the first substrate 21.

Then, the photodiodes 30 are formed on the TFT layer 24 (Step ST12). The photodiodes 30 may be formed by vapor deposition or coating formation. Although illustrated in simplified form in FIG. 11, various electrodes, such as the lower conductive layer 34 and the upper conductive layer 35 coupled to the photodiode 30, are also patterned.

Then, the sensor insulating film 25 is formed so as to cover the photodiodes 30 (Step ST13). The grooves 25a are formed between the adjacent photodiodes 30. The grooves 25a are formed along steps formed by the photodiodes 30 and the TFT layer 24. Alternatively, the grooves 25a may be formed by removing portions of a surface of the sensor insulating film 25 using an etching process, for example.

The process of forming the optical filter 7 will be described below. First, the second substrate 71 and the barrier film 74 are formed on one surface of a support substrate 212 (Step ST14). The second substrate 71 is formed by applying a material of the second substrate 71 on the support substrate 212 and curing the applied material. The support substrate 212 is a glass substrate, for example, and has higher stiffness than that of the second substrate 71. The barrier film 74 is formed on the second substrate 71.

Then, the optical filter layer 75 is formed on the barrier film 74 of the second substrate 71 (Step ST15). As described above, the optical filter layer 75 includes the light-transmitting regions 78, the light-blocking region 76 provided between the light-transmitting regions 78, and the projections 77 projecting from the upper side of the light-blocking region 76. The optical filter layer 75 may be made by forming the light-blocking region 76 from a colored resin material, patterning the light-blocking region 76, and then forming the light-transmitting regions 78 from a light-transmitting resin material. Alternatively, the optical filter layer 75 may be made by forming the columnar light-transmitting regions 78 from a light-transmitting resin material, and then filling the space outside the light-transmitting regions 78 with a colored resin material to form the light-blocking region 76. The areas and the arrangement pitch of the light-transmitting regions 78 in plan view are set correspondingly to the areas and the arrangement pitch of the photodiodes 30 of the array substrate 2. The shape in plan view and the height of the projection 77 are set correspondingly to those of the groove 25a of the sensor insulating film 25.

Then, the sealing member 27 is formed at the periphery of the optical filter layer 75 (Step ST16). The sealing member 27 is provided in a region corresponding to the peripheral region GA and is formed in a frame shape around a region corresponding to the detection region AA.

Then, the adhesive layer 26 of a liquid UV curable resin is applied and formed so as to cover a surface of the optical filter layer 75, and the first substrate 21 (array substrate 2) and the second substrate 71 (optical filter 7) are bonded together (Step ST17). In this process, the first substrate 21 and the second substrate 71 are positioned and bonded together such that the projections 77 are located between the adjacent photodiodes 30 in plan view, more specifically, such that the projections 77 face the bottoms of the grooves 25a. Then, the adhesive layer 26 is irradiated with UV light to be cured. Alternatively, the UV light irradiation and thermal curing may be used in combination, as required.

Then, what is called a laser lift-off technique is used to separate the support substrate 211 from the first substrate 21, and separate the support substrate 212 from the second substrate 71. Then, the protective film 201 is bonded to the first substrate 21, and the protective film 202 is bonded to the second substrate 71 (Step ST18). The detection device 1 can be manufactured by the processes described above.

In the present embodiment, the array substrate 2 and the optical filter 7 are formed in the mutually independent processes, using the first and the second substrates 21 and 71 different from each other, respectively. Therefore, compared with a process of stacking and forming the optical filter layer 75 on the photodiodes 30 of the array substrate 2, the amount of the application of heat and other factors in the process of manufacturing the optical filter layer 75 to the photodiodes 30 and other components of the array substrate 2 are reduced. Thus, damage of the photodiodes 30 of the array substrate 2 can be reduced. Otherwise, the process of manufacturing the optical filter 7 is not restricted by the temperature on the side of the array substrate 2, and thus, the degree of freedom of the material and the process used for the optical filter layer 75 can be improved.

Since the projections 77 are provided in the optical filter layer 75, the positional misalignment can be reduced in the process of bonding the first substrate 21 to the second substrate 71. The first substrate 21 is bonded to the second substrate 71 in the state where the first substrate 21 and the second substrate 71 are bonded to the rigid support substrates 211 and 212, respectively. Therefore, even when the first and the second substrates 21 and 71 are formed as flexible resin substrates, deformation of the first and the second substrates 21 and 71 can be reduced, thereby reducing the positional misalignment in the bonding process.

The method for manufacturing illustrated in FIG. 11 is merely an example and can be changed as appropriate. For example, at Step ST18, the protective film 201 is bonded to the first substrate 21, but the protective film 202 need not be provided on the second substrate 71.

As described above, the detection device 1 of the present embodiment includes the first substrate 21, the photodiodes 30 provided on the first substrate 21, and the optical filter layer 75 that includes the light-transmitting regions 78 each provided so as to overlap a corresponding one of the photodiodes 30, the light-blocking region 76 provided between the light-transmitting regions 78, and the projections 77 projecting from the surface of the light-blocking region 76 facing the first substrate 21.

The method for manufacturing the detection device 1 of the present embodiment includes the process of forming the photodiodes 30 on the first substrate 21 (Step ST12), the process of forming the optical filter layer 75 on the second substrate 71, the optical filter layer 75 including the light-transmitting regions 78, the light-blocking region 76 provided between the light-transmitting regions 78, and the projections 77 projecting from the upper side of the light-blocking region 76 (Step ST15), and the process of bonding the first substrate 21 to the second substrate 71 such that the projections 77 are located between the adjacent photodiodes 30 in plan view in the direction orthogonal to the first substrate 21 (Step ST17).

### Second Embodiment

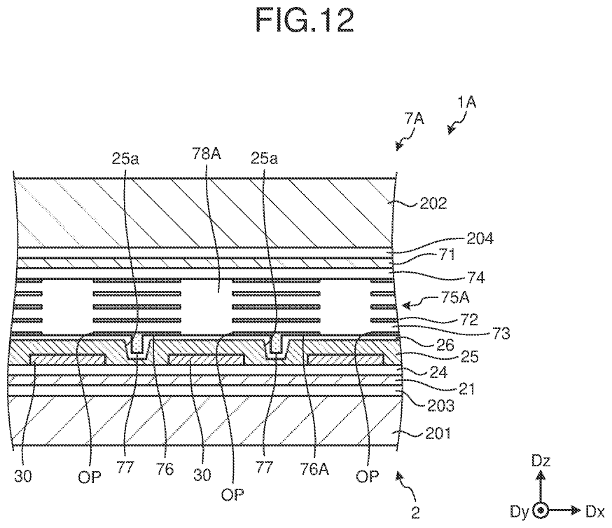

FIG. 12 is a sectional view schematically illustrating a detection device according to a second embodiment. In the following description, the same components as those described in the embodiment described above are denoted by the same reference numerals, and the description thereof will not be repeated.

In the first embodiment described above, the optical filter layer 75 is formed to have a light guide column structure in which the light-transmitting regions 78 are formed in a circular cylindrical shape, but the present disclosure is not limited to this configuration and can employ other configurations. As illustrated in FIG. 12, in an optical filter 7A included in a detection device 1A according to the second embodiment, an optical filter layer 75A is configured such that g a plurality of light-blocking layers 72 and a plurality of light-transmitting resin layers 73 are alternately stacked.

An opening OP is formed in a region of the light-blocking layers 72 that overlaps the photodiode 30. In the present embodiment, a light-blocking region 76A is a region where the opening OP is not formed and at least one layer of the light-blocking layers 72 is provided between one surface and the other surface of the optical filter layer 75A in the third direction Dz. A light-transmitting region 78A is a region where the opening OP is formed and the light-transmitting resin layers 73 are continuously formed from the one surface to the other surface of the optical filter layer 75A in the third direction Dz. The projection 77 is provided in the light-blocking region 76A of the lowermost light-blocking layer 72 (on the first substrate 21 side).

The diameter of the opening OP provided in the light-blocking layers 72 is set to have the same size along the third direction Dz. However, the diameter of the opening OP is not limited to this size, and may vary along the third direction Dz. For example, the diameter of the opening OP may increase as the position approaches the first substrate 21 from the second substrate 71. The number of the light-blocking layers 72 may be six or larger, or four or smaller.

### Third Embodiment

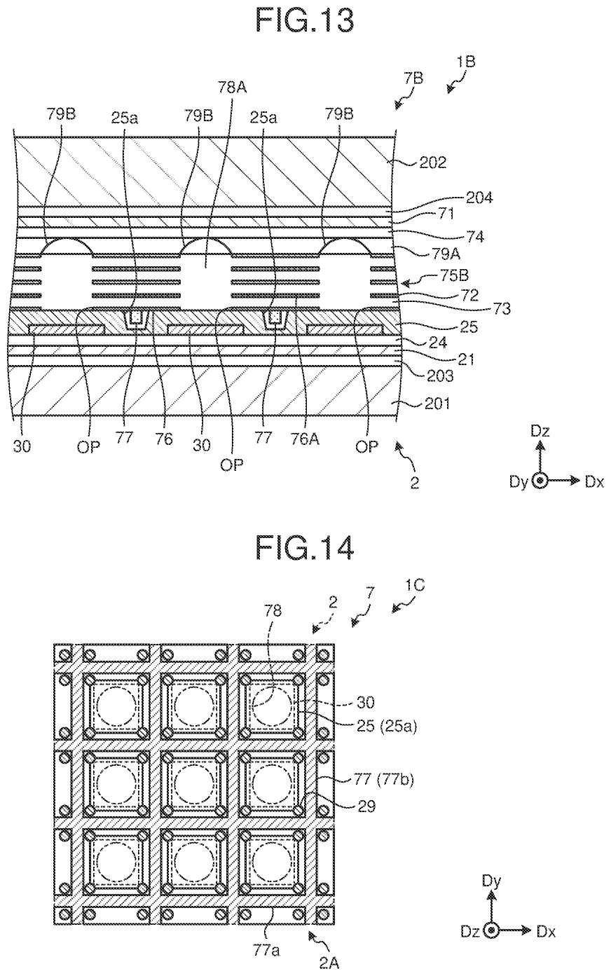

FIG. 13 is a sectional view schematically illustrating a detection device according to a third embodiment. As illustrated in FIG. 13, in an optical filter 7B included in a detection device 1B according to the third embodiment, an optical filter layer 75B includes a low refractive index layer 79A and a plurality of lenses 79B.

The low refractive index layer 79A and the lenses 79B are provided on the second substrate 71 side of the optical filter layer 75B, more specifically, between the topmost light-blocking layer 72 and the barrier film 74 in the third direction Dz. The lenses 79B are provided at locations overlapping the light-transmitting regions 78A and the photodiodes 30. The low refractive index layer 79A is provided between the adjacent lenses 79B so as to cover the lenses 79B and the light-blocking layers 72 (light-blocking regions 76A). The low refractive index layer 79A is formed of a material having a smaller refractive index than that of the lenses 79B.

The light L2 from the object to be detected, such as the finger Fg, is condensed by the lenses 79B, and transmitted through the light-transmitting regions 78A to enter the photodiodes 30. In the present embodiment, the path of the light traveling in the optical filter layer 75B can be appropriately controlled by the lenses 79B. Therefore, the detection device 1B can reduce the occurrences of the crosstalk.

### Fourth Embodiment

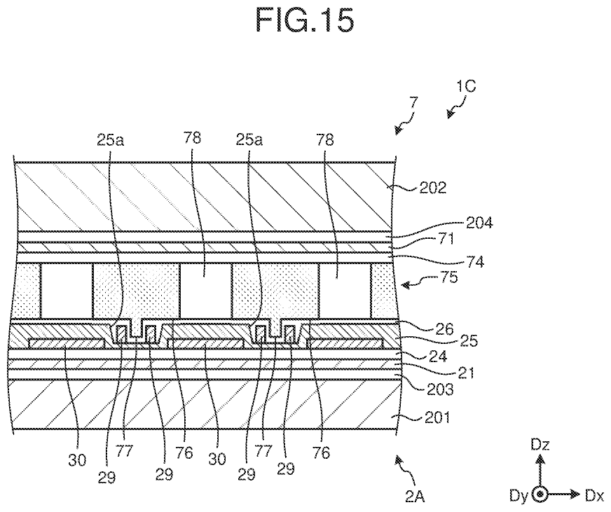

FIG. 14 is an explanatory diagram for schematically explaining an arrangement relation of the projections of the optical filter layer with the photodiodes and the sensor insulating film of the array substrate of a detection device according to a fourth embodiment. FIG. 15 is a sectional view schematically illustrating the detection device according to the fourth embodiment.

As illustrated in FIGS. 14 and 15, in a detection device 1C according to the fourth embodiment, an array substrate 2A includes at least one pair of sensor-side projections 29 provided on the sensor insulating film 25 between the adjacent photodiodes 30. The sensor-side projections 29 project from the bottom of the groove 25a of the sensor insulating film 25 toward the second substrate 71.

As illustrated in FIG. 14, four of the sensor-side projections 29 are provided for one photodiode 30. The sensor-side projections 29 are provided at four respective corners of the projection 77 surrounding the one photodiode 30. In other words, the four sensor-side projections 29 are provided at intersections between the first portions 77a and the second portions 77b of the projections 77.

As illustrated in FIG. 14, the projection 77 (first portion 77a) is located between the one pair of the sensor-side projections 29 adjacent in the second direction Dy. As illustrated in FIGS. 14 and 15, the projection 77 (second portion 77b) is located between the one pair of the sensor-side projections 29 adjacent in the first direction Dx.

As described above, in the fourth embodiment, since the sensor-side projections 29 corresponding to the projection 77 are provided, the positional accuracy between the first substrate 21 (array substrate 2A) and the second substrate 71 (optical filter 7) can be improved.

While FIG. 15 illustrates the optical filter layer 75 having the light guide column structure, the configuration of the fourth embodiment is not limited to this configuration and can be combined with the configuration of the second or the third embodiment described above.

While the preferred embodiments of the present disclosure have been described above, the present disclosure is not limited to the embodiments described above. The content disclosed in the embodiments is merely an example, and can be variously modified within the scope not departing from the gist of the present disclosure. Any modifications appropriately made within the scope not departing from the gist of the present disclosure also naturally belong to the technical scope of the present disclosure. At least one of various omissions, substitutions, and changes of the components can be made without departing from the gist of the embodiments and the modifications described above.

What is claimed is:

1. A detection device comprising:
a first substrate;
a plurality of photodiodes provided on the first substrate; and
an optical filter layer comprising a plurality of light-transmitting regions provided so as to overlap the respective photodiodes, a light-blocking region provided between the light-transmitting regions, and a projection projecting from a surface of the light-blocking region facing the first substrate.

2. The detection device according to claim 1, further comprising a second substrate facing the first substrate with the photodiodes and the optical filter layer interposed between the first substrate and the second substrate, wherein
the light-transmitting regions and the light-blocking region are provided on a surface of the second substrate facing the first substrate.

3. The detection device according to claim 1, further comprising a sensor insulating film covering the photodiodes, wherein
the sensor insulating film is provided with a groove between the adjacent photodiodes, and
the projection is provided in a position overlapping the groove.

4. The detection device according to claim 1, further comprising:
a sensor insulating film covering the photodiodes; and
at least one pair of sensor-side projections provided on the sensor insulating film between the adjacent photodiodes, wherein
the projection is provided between the one pair of the sensor-side projections.

5. The detection device according to claim 1, wherein
the photodiodes are arranged adjacent to one another in a first direction, and
the projection is provided between the photodiodes adjacent in the first direction, and extends in a second direction intersecting the first direction in plan view in a direction orthogonal to the first substrate.

6. The detection device according to claim 1, wherein the projections are provided in a frame shape surrounding each of the photodiodes.

7. The detection device according to claim 1, further comprising:
a plurality of lenses that are provided on a surface opposite to a surface of the optical filter layer facing the first substrate so as to overlap the light-transmitting regions; and
a low refraction layer provided between the adjacent lenses.

8. A method for manufacturing a detection device, the method comprising:
forming a plurality of photodiodes on a first substrate;
forming an optical filter layer comprising a plurality of light-transmitting regions, a light-blocking region provided between the light-transmitting regions, and a projection projecting from an upper side of the light-blocking region; and
bonding the first substrate to the second substrate such that the projection is located between the adjacent photodiodes in plan view in a direction orthogonal to the first substrate.
